(19) United States
(12) Patent Application Publication
(10) Pub. No.: US 2023/0231407 A1
(43) Pub. Date: Jul. 20, 2023

(54) SEMICONDUCTOR DEVICE AND CONTROL METHOD OF CHARGING BATTERY

(71) Applicant: Renesas Electronics Corporation, Tokyo (JP)

(72) Inventors: Masaki HOGARI, Tokyo (JP); Masaru MIYAKE, Tokyo (JP); Yasuo USUDA, Tokyo (JP); Youhei KENGOYAMA, Tokyo (JP); Tetsuo MIYAUCHI, Tokyo (JP)

(73) Assignee: Renesas Electronics Corporation, Tokyo (JP)

(21) Appl. No.: 18/146,708

(22) Filed: Dec. 27, 2022

(30) Foreign Application Priority Data
Jan. 17, 2022 (JP) 2022-005141

(51) Int. Cl. H02J 7/00; H01M 10/42; H01M 10/48; H01M 10/44

(52) U.S. Cl. CPC H02J 7/007194; H02J 7/0047; H01M 10/425; H01M 10/486; H01M 10/443

(57) ABSTRACT

Provided is a semiconductor device capable of stably estimating an internal temperature of a battery. A semiconductor device coupled to a battery calculates entropy heat of the battery at a predetermined time by using a charging current of the battery and an internal temperature of the battery at a time before a predetermined time, calculates a heat generation amount of the battery from the charging current of the battery, calculates a heat radiation amount of the battery based on a temperature difference between the internal temperature at the time before the predetermined time and a surface temperature of the battery, and estimates an internal temperature of the battery at the predetermined time by using the entropy heat, the heat generation amount and the heat radiation amount.

### CROSS-REFERENCE TO RELATED APPLICATIONS

The subject application claims priority to Japanese Patent Application No. 2022-005141, filed on Jan. 17, 2022. The disclosure of Japanese Patent Application No. 2022-005141, including the specification, drawings and abstract, is incorporated herein by reference in its entirety.

### BACKGROUND

The present invention relates to a semiconductor device and a control method of charging a battery, and for example, relates to a semiconductor device that charges a battery (a secondary battery) such as a lithium-ion battery and to a control method of charging the battery.

For example, there is a disclosed technique listed below.
[Patent Document 1] International Patent Publication No. WO 2016/038658

Patent Document 1 describes a technology for measuring a surface temperature of a battery and a temperature (an ambient temperature) of an external environment where the battery is present and controlling charging of the battery.

### SUMMARY

When a temperature difference between the surface temperature of the battery and the ambient temperature is large, it is effective to use the ambient temperature in order to estimate an internal temperature of the battery, for example, as shown in Patent Document 1. However, in terms of a structure of the battery, the temperature difference between the surface temperature of the battery and the ambient temperature is usually small, and the ambient temperature does not contribute to such estimation of the internal temperature of the battery. Hence, it is conceivable to estimate the internal temperature of the battery by using the surface temperature, and to control the charging of the battery on the basis of the surface temperature and the estimated internal temperature. However, in this case, for example, the surface temperature sometimes becomes higher than the ambient temperature depending on usage of the battery, and it sometimes becomes difficult to accurately estimate the internal temperature of the battery by the surface temperature.

Patent Document 1 neither describes nor suggests that the internal temperature of the battery is accurately estimated without using the ambient temperature.

Outlines of representatives in embodiments disclosed in the present application will be briefly described below.

That is, a semiconductor device coupled to a battery includes: a control unit that is supplied with a charging current of the battery, a voltage of the battery, and a surface temperature of the battery, and estimates an internal temperature of the battery; and a memory that stores the internal temperature estimated by the control unit. Herein, the control unit calculates entropy heat of the battery at a predetermined time by using the supplied charging current and an internal temperature at a time before the predetermined time, the internal temperature being stored in the memory, calculates a heat generation amount of the battery from the supplied charging current, obtains a temperature difference between the internal temperature at the time before the predetermined time, the internal temperature being stored in the memory, and the supplied surface temperature, and calculates a heat radiation amount of the battery from the temperature difference, and estimates an internal temperature of the battery at the predetermined time by using the calculated entropy heat, the calculated heat generation amount, and the calculated heat radiation amount.

Moreover, in a semiconductor device according to another embodiment, the charging current at a time of charging the battery is determined based on the estimated internal temperature.

Other objects and novel features will be apparent from the description in the specification and the accompanying drawings.

In accordance with an embodiment, it becomes possible to stably estimate the internal temperature of the battery not by using the ambient temperature of the battery, which is uncertain, but by using the surface temperature of the battery.

### BRIEF DESCRIPTION OF THE DRAWINGS

FIG. 1 is a flowchart for explaining an internal temperature estimation process according to a first embodiment.

FIG. 2 is a partial perspective view showing an example of a battery pack according to the first embodiment.

FIG. 3 is a view showing formulas for use in the internal temperature estimation process according to the first embodiment.

FIG. 4 is a block diagram showing a configuration of a charging system according to a second embodiment.

FIG. 5 is a flowchart for explaining an overall operation of the charging system according to the second embodiment.

FIG. 6 is a flowchart showing operations of the charging system according to the second embodiment.

FIG. 7 is a characteristic diagram showing characteristics during charging in Comparative example 1.

FIG. 8 is a characteristic diagram showing characteristics during charging in Comparative example 2.

FIG. 9 is a characteristic diagram showing characteristics during charging in Comparative example 3.

FIG. 10 is a characteristic diagram showing characteristics during charging in Comparative example 4.

FIG. 11 is a characteristic diagram showing characteristics of the charging system according to the second embodiment.

FIG. 12 is a flowchart showing operations of a charging system according to a third embodiment.

### DETAILED DESCRIPTION

Hereinafter, a description will be given of respective embodiments of the present invention with reference to the drawings. Note that the disclosure is merely an example, and appropriate changes of the invention, which maintain the spirit thereof and are easily conceivable by those skilled in the art, are naturally included in the scope of the present invention.

Moreover, in some cases, in the present specification and the respective drawings, the same reference numerals are assigned to elements similar to those mentioned above regarding the already-discussed drawings, and a detailed description thereof is omitted as appropriate.

### First Embodiment

In a first embodiment, a description will be given of a process (an internal temperature estimation process) of estimating an internal temperature of a battery on the basis of a surface temperature of the battery.

The internal temperature estimation process is executed in a semiconductor device packed in a battery pack together with the battery. Regarding the semiconductor device, an example thereof will be described later (in a second embodiment), and accordingly, a detailed description of the semiconductor device will be omitted herein, and only portions necessary in the description of the first embodiment will be mainly described.

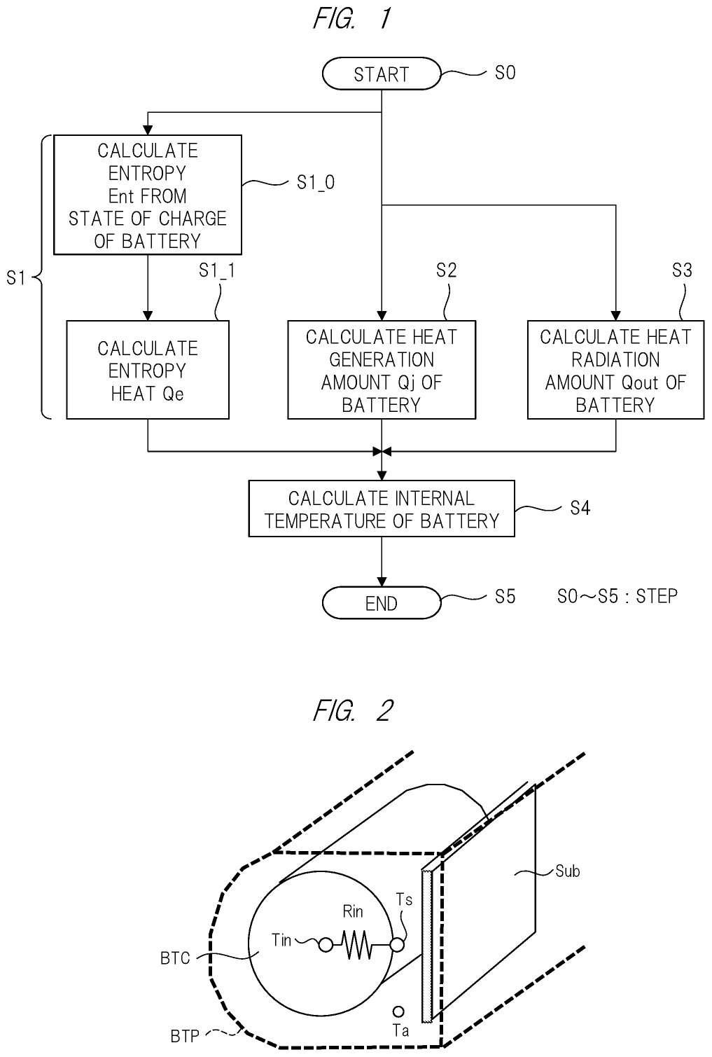

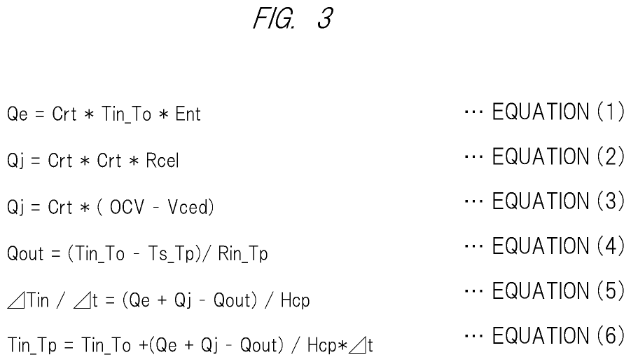

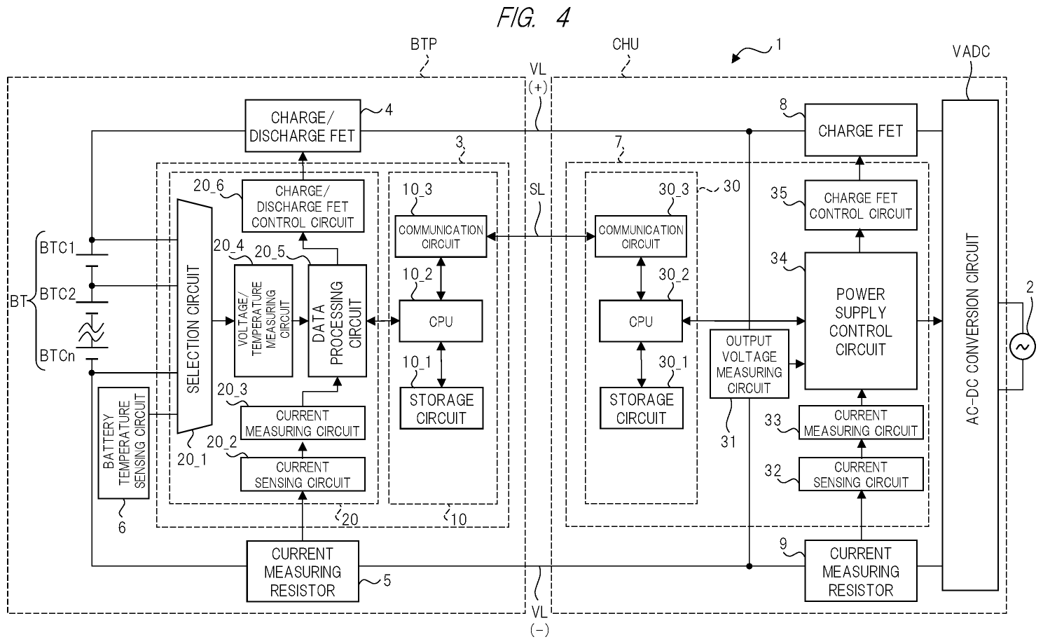

FIG. 1 is a flowchart for explaining the internal temperature estimation process according to the first embodiment. FIG. 2 is a partial perspective view showing an example of a battery pack according to the first embodiment. Moreover, FIG. 3 is a view showing formulas for use in the internal temperature estimation process according to the first embodiment.

In FIG. 2, reference symbol BTP denotes a battery pack. The battery pack BTP is provided with a battery composed of one or a plurality of battery cells BTC, and with a substrate Sub on which a semiconductor device and the like are packaged. FIG. 2 shows an example of a battery composed of one battery cell BTC; however, the battery is not limited to this. When the battery is composed of the plurality of battery cells BTC, the plurality of battery cells BTC are connected, for example, in series to one another, and the respective battery cells BTC are coupled to the semiconductor device packaged on the substrate Sub. When the battery pack BTP is coupled to an electronic instrument, a discharge voltage of the battery in the battery pack BTP is supplied as a power supply to the electronic instrument.

At the time of charging the battery in the battery pack BTP, the semiconductor device packaged on the substrate Sub supplies state information (battery state information), which is related to the battery coupled thereto, to a charging device (not shown). The charging device charges the battery on the basis of the state information supplied thereto. Hereinafter, in the present specification, a system including the battery pack BTP and the charging device will also be referred to as a charging system.

In FIG. 2, reference symbol Tin denotes an internal temperature of the battery (the battery cell BTC), and reference symbol Ts denotes a surface temperature of the battery (the battery cell BTC). Moreover, reference symbol Rin denotes a temperature resistance (a temperature impedance) of the battery, and reference symbol Ta denotes an ambient temperature of an outside (an inside of the battery pack BTP) of the battery that is present. A difference between the surface temperature Ts and the ambient temperature Ta is that, while the surface temperature Ts is a temperature on the surface of the battery, the ambient temperature Ta is a temperature at a predetermined position in air in the battery pack BTP.

In the first embodiment, the surface temperature Ts is measured by a temperature sensor (not shown) installed on the surface of the battery, and is reported to the semiconductor device.

The semiconductor device includes a memory, a processor core, and the like. The memory stores data such as an internal temperature of the battery, entropy of the battery and the temperature resistance of the battery at a time (a past time To) before a predetermined time (for example, a current time Tp). By using the data stored in the memory, the surface temperature Ts at the current time (Tp), which is measured by the temperature sensor, a charging current, and the like, the semiconductor device executes the internal temperature estimation process shown in FIG. 1, and estimates the internal temperature Tin of the battery at the current time (Tp).

Next, the internal temperature estimation process of the battery will be described with reference to FIG. 1. The internal temperature estimation process is achieved in such a manner that the processor core built in the semiconductor device executes a program while using the memory also built in the semiconductor device. That is, the program is executed, whereby Steps S0 to S5 in FIG. 1 are carried out by the processor core. The internal temperature estimation process is started in Step S0. Subsequently to Step S0, Steps S1, S2 and S3 are executed. In the internal temperature estimation process according to the first embodiment, Steps S1 to S3 are carried out concurrently with one another, but are not limited to this.

In Step S1, entropy heat Qe of the battery is calculated on the basis of the internal temperature Tin_To at the past time (To), which is stored in the memory, entropy Ent of the battery at the current time (Tp), and a charging current Crt. In the first embodiment, the memory stores plural pieces of entropy Ent, which correspond to states of charge (SOCs) of the batteries, as a table (an entropy table).

Step S1 is composed of Step S1_0 and Step S1_1. In Step S1_0, entropy Ent corresponding to the state of charge (SOC) of the battery at the current time is obtained from the entropy table. That is, from the state of charge of the battery, the entropy Ent corresponding thereto is calculated. The calculated entropy Ent is used in the next Step S1_1. The entropy Ent is a coefficient corresponding to the state of charge of the battery. A user obtains in advance plural pieces of entropy Ent, which correspond to states of charge different from one another, and as described above, stores the plural pieces of entropy as the entropy table in the memory.

In Step S1_1, the entropy heat Qe is calculated. A formula for calculating the entropy heat Qe is shown as Equation (1) in FIG. 3. As seen from Equation (1) shown in FIG. 3, the entropy heat Qe of the battery is a product of the charging current Crt, the internal temperature Tin_To at the past time, and the entropy Ent.

In Step S2, a heat generation amount (Joule heat) Qj of the battery is calculated. A formula for calculating the heat generation amount Qj is shown as Equation (2) or Equation (3) in FIG. 3. The heat generation amount Qj may be calculated by Equation (2), or may be calculated by Equation (3). In Equation (2), reference symbol Rcel denotes an internal resistance of the battery at the current time (Tp). Moreover, in Equation (3), reference symbol OCV denotes an open voltage of the battery at the current time (Tp), and reference symbol Vced denotes a voltage of the battery at the current time (Tp).

In the case of Equation (2), the heat generation amount Qj becomes a product of a square of the charging current Crt and the internal resistance Rcel of the battery. Moreover, in the case of Equation (3), the heat generation amount Qj becomes a product obtained by multiplying, by the charging current Crt, a subtraction value between the open voltage OCV and the battery voltage Vced. That is, the heat generation amount Qj is calculated on the basis of the charging current Crt.

In Step S3, a heat radiation amount Qout of the battery is calculated. A formula for calculating the heat radiation amount Qout is shown as Equation (4) in FIG. 3. In Equation (4), reference symbol Ts Tp denotes a surface temperature of the battery at the current time (Tp), and reference symbol Rin TP applies to the temperature resistance Rin of the battery, and denotes a temperature resistance value at the current time (Tp). As seen from Equation (4) in FIG. 3, the heat radiation amount Qout is calculated in such a manner that a temperature difference between the surface temperature Ts Tp at the current time and the internal temperature Tin_To at the past time (To) is divided by the temperature resistance Rin TP. That is, the heat radiation amount Qout is calculated on the basis of the temperature difference between the surface temperature at present and the internal temperature in the past.

The entropy heat Qe, the heat generation amount Qj and the heat radiation amount Qout, which are calculated in Steps S1 to S3, are supplied to Step S4. In Step S4, by using these, the processor core calculates the internal temperature Tin of the battery at the current time. Formulas for calculating the internal temperature Tin at the current time (Tp) are shown as Equation (5) and Equation (6) in FIG. 3. In Equation (5) and Equation (6), reference symbol Hcp denotes a heat capacity of the battery. Moreover, reference symbol Δt denotes a time difference between the past time (To) and the current time (Tp), and reference symbol ΔTin denotes a variation of the internal temperature Tin that changes during the time difference Δt.

As seen from Equation (5) in FIG. 3, a value obtained by subtracting the heat radiation amount Qout from the sum of the entropy heat Qe and the heat generation amount Qj is divided by the heat capacity Hcp, whereby the variation of the internal temperature Tin during the time difference Δt is calculated. Hence, as shown in Equation (6), the variation ΔTin is multiplied by the time difference Δt, and the internal temperature Tin_To at the past time (To) is added to a product thus obtained, whereby the internal temperature Tin Tp at the current time (Tp) can be calculated. The internal temperature Tin Tp thus calculated is stored in the memory, and is used as the internal temperature Tin_To in the next internal temperature estimation process. Moreover, the calculated internal temperature Tin Tp is used as the estimated internal temperature Tin at the current time (Tp) for a charging control at the time of charging the battery.

In Step S5, the internal temperature estimation process is ended. Steps S1 to S5 are repeated, the internal temperature Tin of the battery, which changes with the elapse of time, will be estimated.

In accordance with the internal temperature estimation process of the battery according to the first embodiment, the internal temperature of the battery can be estimated not by using the ambient temperature of the battery but by using only the surface temperature of the battery. That is, in accordance with the first embodiment, the internal temperature of the battery can be estimated without using the ambient temperature that is uncertain, and an estimated value of the internal temperature can be stabilized.

Moreover, in the internal temperature estimation process according to the first embodiment, it becomes unnecessary to perform a process related to the ambient temperature, and accordingly, it becomes possible to shorten a processing time. The processing time for the internal temperature estimation process is shortened, whereby it is possible to accelerate a response to a sudden change of a state of the battery at the time of charging the battery (for example, a response to a sudden change of the surface temperature).

### Second Embodiment

Next, a charging system that adopts the internal temperature estimation process described in the first embodiment will be described with reference to the drawings.

FIG. 4 is a block diagram showing a configuration of a charging system according to the second embodiment. In FIG. 4, reference numeral 1 denotes a charging system. The charging system 1 includes the battery pack BTP, and a charging device CHU that charges the battery BT in the battery pack BTP. The battery pack BTP is coupled to the charging device CHU by power supply lines VL (+) and VL (−) and a signal line SL. The charging device CHU is coupled, for example, to a commercial power supply (AC100V) 2.

At the time of charging the battery BT, state information of the battery BT is supplied from the battery pack BTP through the signal line SL to the charging device CHU. For example, the charging device CHU drops a power supply voltage output from the commercial power supply 2, and supplies a voltage and a current to the power supply lines VL (+) and VL (−) according to the state information of the battery BT. The battery BT is charged with the voltage and the current, which are supplied from the charging device CHU.

Configuration of Battery Pack BTP The battery pack BTP includes the battery BT, a battery managing semiconductor device 3, a charging/discharging transistor (a charge/discharge FET) 4, a current sensor (a current measuring resistor) 5, and a temperature sensor (a battery temperature sensing circuit) 6. The battery managing semiconductor device 3, the charging/discharging transistor 4 and the current sensor 5 are packaged on the substrate Sub shown in FIG. 2. Moreover, the temperature sensor 6 is provided on the surface of the battery BT.

In FIG. 4, the battery BT is not particularly limited, but is composed of n pieces of battery cells BTC1 to BTCn connected in series to one another. A positive electrode of the battery BT is connected to the power supply line VL (+) through the charging/discharging transistor 4, and a negative electrode thereof is connected to the power supply line VL (−) through the current sensor 5. Moreover, positive electrodes and negative electrodes of the battery cells BTC1 to BTCn are individually connected to the semiconductor device 3. The temperature sensor 6 provided on the surface of the battery BT is also connected to the semiconductor device 3.

At the time of charging the battery BT, the semiconductor device 3 controls the charging/discharging transistor 4 so that the voltage and the current are supplied from the charging device CHU through the power supply line VL (+) to the battery BT. Meanwhile, when the battery pack BTP is connected to the electronic device (not shown), and electric power is supplied from the battery pack BTP to the electronic device, the semiconductor device 3 controls the charging/discharging transistor 4 so that the voltage and the current, which are supplied from the battery BT, are output from the battery pack BTP.

At the time of charging the battery BT, the current sensor 5 measures a charging current, which flows through the power supply line VL (−), and supplies a measurement result to the semiconductor device 3. Although not particularly limited, the current sensor 5 is composed of a shunt resistor connected between the power supply line VL (−) and the negative electrode of the battery pack BTP. A voltage corresponding to the charging current that flows through the shunt resistor is supplied as a value (a measurement result) of the charging current to the semiconductor device 3.

The temperature sensor 6 supplies the measured surface temperature of the battery to the semiconductor device 3.

Battery Managing Semiconductor Device 3

The semiconductor device 3 includes a plurality of circuit blocks, but FIG. 4 shows only a circuit block necessary to describe the present embodiment. In FIG. 4, reference numeral 20 denotes an analog circuit block (an analog block) that is connected to the battery BT, the charging/discharging transistor 4 and the current sensor 5 and mainly performs an analog process. Moreover, reference numeral 10 denotes a processor circuit block (hereinafter, also referred to as a processor unit) connected to the analog block 20 and the signal line SL.

The analog block 20 includes a selection circuit 20_1, a current sensing circuit 20_2, a current measuring circuit 20_3, a voltage/temperature measuring circuit 20_4, a data processing circuit 20_5, and a charging/discharging transistor control circuit (a charge/discharge FET control circuit) 20_6.

The selection circuit 20_1 is supplied with voltage information from the battery BT and the battery cells BTC1 to BTCn, and with temperature information sensed by the temperature sensor 6. From the supplied voltage information and temperature information, the selection circuit 20_1 sequentially selects voltage information and temperature information, and supplies the selected voltage information and temperature information to the voltage/temperature measuring circuit 20_4. The voltage/temperature measuring circuit 20_4 measures voltages of the battery BT and the battery cells BTC from the supplied voltage information, and measures a surface temperature of the battery BT from the supplied temperature information. The voltages of the battery BT and the battery cells BTC1 to BTCn and the surface temperature of the battery, the voltages and the surface temperature being measured by the voltage/temperature measuring circuit 20_4, are supplied to the data processing circuit 20_5.

The current sensing circuit 20_2 is connected to the current sensor 5, and senses whether or not a charging current is flowing on the basis of a measurement result from the current sensor 5. When the charging current flows, the current measuring circuit 20_3 measures a value of the charging current that is flowing. The value of the charging current, which is measured by the current measuring circuit 20_3, is supplied to the data processing circuit 20_5.

The data processing circuit 20_5 notifies the charging/discharging transistor control circuit 20_6 whether the battery BT is to be charged or discharged. According to such a notice, the charging/discharging transistor control circuit 20_6 controls the charging/discharging transistor 4 as described above. Moreover, the data processing circuit 20_5 performs predetermined processes for the supplied voltage value of the battery BT (including the battery cells BTC1 to BTCn) and the supplied surface temperature and charging current value of the battery BT, and supplies the processed voltage value, surface temperature and charging current value to the processor unit 10.

The processor unit 10 includes a processor core (hereinafter, also referred to as a control unit) 10_2, a communication circuit 10_3, and a memory (a storage circuit) 10_1.

In accordance with a program (not shown), the processor core 10_2 performs a charging process, which includes the internal temperature estimation process described in the first embodiment, while using data stored in the memory 10_1. The state information of the battery BT, which is created by execution of the charging process in the processor core 10_2, is supplied to the charging device CHU through the signal line SL by the communication circuit 10_3.

Moreover, though not particularly limited, an instruction from the charging device CHU to the battery pack BTP is supplied to the communication circuit 10_3 through the signal line SL, and is supplied to the processor core 10_2. In accordance with the supplied instruction, the processor core 10_2 controls the data processing circuit 20_5 for example.

Configuration of Charging Device

The charging device CHU includes a charging controlling semiconductor device 7 that controls the charging to the battery, a charging transistor (a charge FET) 8, a current sensor (a current measuring resistor) 9, and an alternating current/direct current conversion circuit (an AC-DC conversion circuit) VADC.

In accordance with an instruction from the semiconductor device 7, the alternating current/direct current conversion circuit VADC converts an alternating current voltage, which is supplied from the commercial power supply 2, into a direct current voltage, and outputs the direct current thus converted.

The charging transistor 8 is connected between the power supply line VL (+) and the alternating current/direct current conversion circuit VADC, and in accordance with an instruction from the semiconductor device 7, supplies the direct current voltage, which is output from the alternating current/direct current conversion circuit VADC, to the power supply line VL (+) at the time of charging the battery BT.

The current sensor 9 is provided with a configuration similar to that of the current sensor 5, and is connected between the power supply line VL (−) and the alternating current/direct current conversion circuit VADC. At the time of charging the battery BT, the current sensor 9 measures a current, which flows through the power supply line VL (−), and notifies the semiconductor device 7 of a measurement result.

Like the semiconductor device 3, the semiconductor device 7 is also composed of a plurality of circuit blocks, but FIG. 4 shows only a circuit block necessary to describe the present embodiment. The semiconductor device 7 includes a processor unit 30, an output voltage measuring circuit 31, a current sensing circuit 32, a current measuring circuit 33, a power supply control circuit 34, and a charging transistor control circuit (a charge FET control circuit) 35.

The current sensing circuit 32 senses whether or not the charging current is flowing on the basis of a measurement result from the current sensor 9. When the current sensing circuit 32 senses that the charging current is flowing, the current measuring circuit 33 measures a charging current value on the basis of the measurement result of the current sensor 9. The charging current value thus measured is supplied to the power supply control circuit 34.

The output voltage measuring circuit 31 measures a voltage between the power supply lines VL (+) and VL (−), that is, an output voltage of the charging device CHU, and outputs a voltage value thus measured to the power supply control circuit 34.

The processor unit 30 includes a processor core (a control unit) 30_2, a memory (a storage circuit) 30_1, and a communication circuit 30_3. In accordance with a program (not shown), the processor core 30_2 performs a predetermined operation while using the memory 30_1 and the communication circuit 30_3. For example, at the time of charging the battery BT, the processor core causes the communication circuit 30_3 to receive the state information of the battery BT, which is supplied through the signal line SL. In accordance with the state information of the battery BT, which is received by the communication circuit 30_3, the processor core 30_2 sets the value of the charging current, and the like to the power supply control circuit 34.

The power supply control circuit 34 controls the conversion in the alternating current/direct current conversion circuit VADC on the basis of the current value from the current measuring circuit 33, the voltage value from the output voltage measuring circuit 31 and the value set by the processor core 30_2. Moreover, at the time of charging the battery BT, by using the charging transistor control circuit 35, the power supply control circuit 34 controls the output of the alternating current/direct current conversion circuit VADC to be supplied to the power supply line VL (+) through the charging transistor 8.

Overall Operation of Charging System

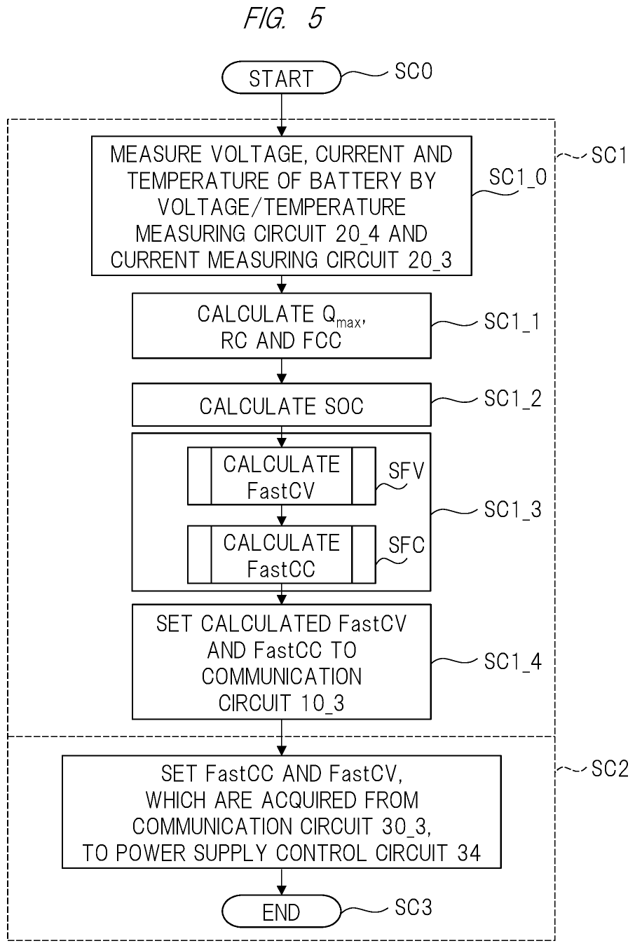

FIG. 5 is a flowchart for explaining an overall operation of the charging system according to the second embodiment. The overall operation of the charging system 1 according to the second embodiment will be described with reference to FIGS. 4 and 5. In the charging system 1 according to the second embodiment, the battery BT is charged by fast constant current charging (FastCC) of making charge at a constant charging current and fast constant voltage charging (FastCV) of making charge at a constant charging voltage. That is, at the beginning, the battery BT is charged by the fast constant current charging, and thereafter, the charging switches to the fast constant voltage charging, and the battery BT is charged by the fast constant voltage charging.

Note that, in the present specification, the operation will be described by using an example of adopting the fast charging (the fast constant voltage charging and the fast constant current charging); however, the term “fast” does not mean that the charging current and the charging voltage are limited to specific ranges. Hence, charging currents and charging voltages, which have varieties of values, are applicable.

In Step SC0, the charging system 1 starts the operation. The next Step SC1 is a step executed mainly in the battery managing semiconductor device 3.

First, in Step SC1_0, the voltage/temperature measuring circuit 20_4 and the current measuring circuit 20_3 measure the voltages of the battery BT and the battery cells BTC1 to BTCn, the charging current of the battery BT, and the surface temperature of the battery BT.

Next, on the basis of the voltage, a charging current and surface temperature of the battery BT, which are measured in Step SC1_0, an ideal capacity (Qmax) of the battery, a battery remaining capacity (RC), and a dischargeable capacity (FCC) of the battery, which are retrievable when the battery BT is in an open circuit (OCV) state, are calculated by the processor core 10_2 in Step SC1_1.

In the next Step SC1_2, the state of charge (SOC) of the battery BT is calculated by the processor core 10_2 by using the ideal capacity (Qmax), the battery remaining capacity (RC) and the dischargeable capacity (FCC) of the battery, which are calculated in Step SC1_1, and by using a state of charge (SOC Fin) at a discharge end point where it is actually possible to discharge the battery BT. Examples of formulas for calculating the state of charge SOC are the following Equation (7) and Equation (8).

FCC=Q max×((100−SOC_Fin)/100) Equation (7)

SOC(%)=RC/FCC×100 Equation (8)

Subsequently to Step SC1_2, Step SC1_3 is executed. Step SC1_3 is composed of two steps, which are Step SFV and Step SFC, and in Step SC1_3, charging current and voltage and the like in the case of performing the fast charging are calculated by the processor core 10_2. That is, in Step SFV, a voltage value and the like in the case of making charge by the fast constant voltage charging (FastCV) are calculated by the processor core 10_2, and in Step SFC, a charging current value and the like in the case of making charge by the fast constant current charging (FastCC) are calculated by the processor core 10_2.

In Step SC1_4, the values of the fast constant voltage charging (FastCV) and the fast constant current charging (FastCC), which are calculated in Step SC1_3, are supplied to the communication circuit 10_3 and set to the communication circuit 10_3 by the processor core 10_2.

In Step SC1_4, the values of the fast constant voltage charging (FastCV) and the fast constant current charging (FastCC), which are set to the communication circuit 10_3, are supplied as the state information of the battery BT through the signal line SL to the communication circuit 30_3 in the charging device CHU, and the communication circuit 30_3 acquires the state information of the battery BT.

In Step SC2, the processor unit 30 sets the state information of the battery BT, which is acquired by the communication circuit 30_3, to the power supply control circuit 34.

In order that the battery BT can be charged in accordance with the set state information (the charging current value and voltage value and the like of the battery BT), the power supply control circuit 34 controls the alternating current/direct current conversion circuit VADC, and controls the charging transistor 8 by the charging transistor control circuit 35.

When the charging of the battery BT is completed, the charge by the charging system 1 is ended in Step SC3.

Since the internal temperature estimation process described in the first embodiment is carried out in Step SC1_3, Step SC1_3 will be described next with reference to the drawings.

Fast Constant Current Charging and Fast Constant Voltage Charging

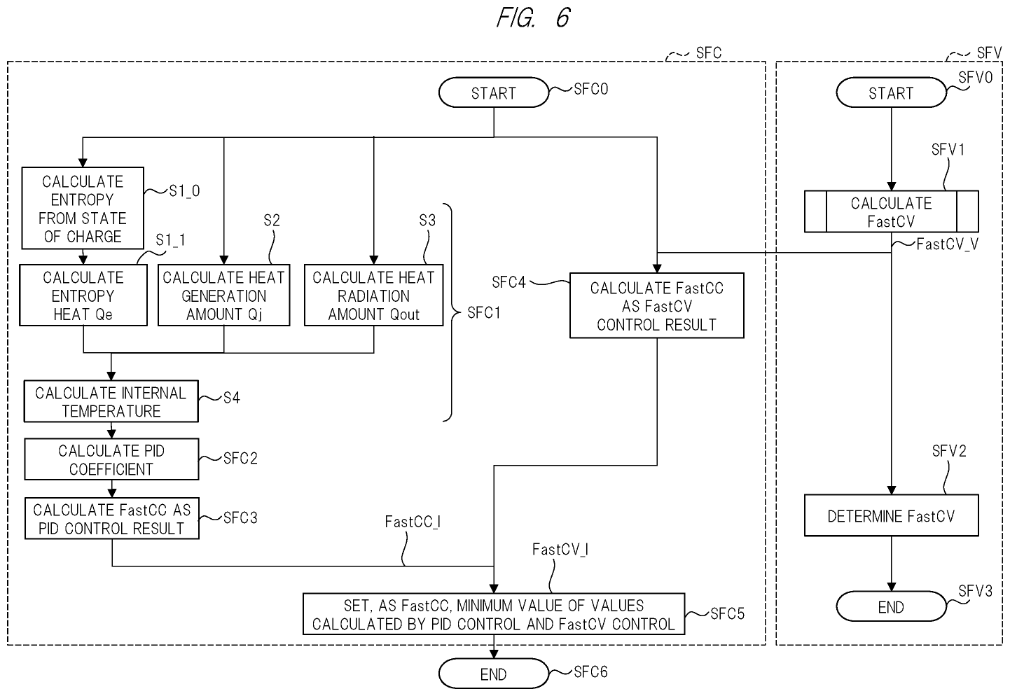

FIG. 6 is a flowchart showing operations of the charging system according to the second embodiment.

In the case of charging the battery BT by the fast constant current charging and the fast constant voltage charging, a normal charging system monitors the voltage and charging current of the battery BT, and controls the charging by using, as parameters, the voltage and the charging current, which are obtained by the monitoring. In the charging system according to the second embodiment, the estimated internal temperature is also used for controlling the charging as described in the first embodiment. That is, as a parameter for use in the charging control, the estimated internal temperature is also added besides two, which are the voltage and charging current of the battery.

In the second embodiment, the estimated internal temperature is added as a parameter in the control (Step SFC in FIG. 5) for the fast constant current charging (FastCC). That is, the internal temperature estimation process described in the first embodiment is added to the process of the fast constant current charging.

In FIG. 6, reference symbol SFC denotes a step (a process) of the fast constant current charging (FastCC) corresponding to Step SFC denoted by the same reference symbol in FIG. 5, and reference symbol SFV denotes a step (a process) of the fast constant voltage charging (FastCV) corresponding to Step SFV denoted by the same reference symbol in FIG. 5. Although not particularly limited, Step SFC and Step SFV are executed by the processor unit 10 provided in the semiconductor device 3 shown in FIG. 4. In this case, the processor unit 10 executes Step SFC and Step SFV concurrently with each other.

First, Step SFV of the fast constant voltage charging will be described. Step SFV starts in Step SFV0. In the next Step SFV1, a value of a voltage applied to the battery BT at the time of the fast constant voltage charging, or the like is calculated. Such a voltage value FastCV V calculated in Step SFV1 is supplied to Step SFC of the fast constant current charging. Moreover, in Step SFV2, the voltage value calculated in Step SFV1, or the like is determined as one for use in the fast constant voltage charging. Thereafter, Step SFV is ended in Step SFV3.

Process for Fast Constant Current Charging Next, Step SFC of the fast constant current charging will be described. Step SFC is composed of Step SFC0 to Step SFC5. When Step SFC starts in Step SFC0, then Step SFC1 and Step SFC4 start concurrently with each other.

Since Step SFC1 is the same as in the flowchart (Steps S1 to S4) described in FIG. 1 according to the first embodiment, a description thereof will be omitted. As described in the first embodiment, in Step S4, the internal temperature of the battery at the current time is estimated on the basis of the surface temperature of the battery BT and the internal temperature at the past time, which is stored in a memory. Note that, in the second embodiment, the memory 10_1 shown in FIG. 4 is used as the memory that stores the internal temperature at the past time, or the like.

In Step SFC2, performed is a PID control using the internal temperature of the battery BT at the current time, which is obtained by the calculation in Step SFC1, and a preset internal temperature (hereinafter, also referred to as a target temperature) of the battery. In the PID control, such a PID coefficient that reduces a temperature difference between the estimated internal temperature and the target temperature is calculated by the processor core 10_2. Note that the target temperature is preset in the memory 10_1 (FIG. 4) for example.

In Step SFC3, the processor core 10_2 calculates a charging current FastCC_I as a PID control result on the basis of the PID coefficient calculated in Step SFC2. An example of a formula for use in an arithmetic operation in Step SFC3 is the following Equation (9). In Equation (9), reference symbol MaxFCC denotes a maximum current value at the time of the fast constant current charging.

FastCC_I=PID coefficient*MaxFCC Equation (9)

In Step SFC4, by using the voltage value FastCV V of the fast constant voltage charging, which is calculated in Step SFV1, the processor core 10_2 calculates a value of a charging current (a constant voltage charging current) FastCV_I at the time of the control of the fast constant voltage charging. The value of the charging current FastCV_I can be calculated, for example, by dividing a value, which is obtained by subtracting the current voltage (a closed voltage) of the battery BT from the voltage value FastCV V, by an internal resistance (an internal impedance) of the battery pack BTP, or the like.

In the charging system 1 according to the second embodiment, in Step SFC5, a value of the charging current FastCC_I, which is calculated in Step SFC3, and the value of the charging current FastCV_I, which is calculated in Step SFC4, are compared with each other, and such a charging current with a lower value is selected, and the selected charging current is set to charge the battery BT. That is, in Step SFC5, the processor core 10_2 compares the charging current FastCC_I related to the fast constant current charging and the charging current FastCV_I related to the fast constant voltage charging with each other, and selects one with a smaller current value. The battery BT is charged with the charging current thus selected.

Thereafter, Step SFC is ended in Step SFC6.

Steps SFC and SFV shown in FIG. 6 are repeatedly executed, and such charging current values set in Step SFC5 are supplied as the state information of the battery BT to the charging device CHU.

New Problem by Adding Estimated Internal Temperature as Parameter

As described above, the normal charging system has controlled the charging by using the voltage and charging current of the battery as parameters. For example, in a region (hereinafter, also referred to as a CC region) where the fast constant current charging (FastCC) is performed, the charging current of the battery has been used as a main parameter, and in a region (hereinafter, also referred to as a CV region) where the fast constant voltage charging (FastCV) is performed, the voltage of the battery has been used as a main parameter, whereby it has been possible to switch the charging control method while distinguishing the CC region and the CV region from each other.

When the flowchart shown in FIG. 6 is applied to such a normal charging system, Steps SFC4 and SFC5 are no longer necessary. In this case, a new problem to be mentioned below occurs.

That is, in the CV region, the charging current is no longer limited by the estimated internal temperature, and accordingly, it is apprehended that the battery BT may be overcharged. Meanwhile, when the battery BT is charged by using the charging current FastCC_I, which is calculated in Step SFC3, in the entire region (a region including the CC region and the CV region) without distinguishing the CC region and the CV region from each other, a temperature range cannot be fully utilized, the charging current is limited, and a charging time of the battery BT is extended, and it is conceived that a charging time loss occurs.

In the second embodiment, Steps SFC and SFV are executed in both of the fast constant current charging and the fast constant voltage charging. That is, both of the charging currents FastCC_I and FastCV_I are calculated in the entire region, and the value of the charging current that charges the battery BT is determined by a smaller charging current between the calculated charging current FastCC_I and FastCV_I. Hence, when the value of the charging current FastCC_I is small in the CV region, the charging current that charges the battery BT is limited by the internal temperature, and the battery BT can be avoided being overcharged.

Moreover, when the value of the charging current FastCV_I is small, the battery BT can be charged with such a charging current that is not limited by the internal temperature, and accordingly, the battery BT can be charged with a value of such a charging current in which the temperature range is fully utilized to an upper limit thereof, and charging efficiency can be maximized.

That is, in accordance with the second embodiment, even if the estimated internal temperature is added as a new parameter at the time of performing the charging control, the battery can be prevented from being overcharged, and it also becomes possible to prevent the charging time loss from occurring.

In accordance with the charging system 1 according to the second embodiment, the charging efficiency can be maximized while achieving the fast charging using the fast constant current charging and the fast constant voltage charging, and accordingly, an overall loss can also be reduced. Moreover, it is possible to prevent overheating or over temperature of the battery BT, and accordingly, degradation of the battery BT can be suppressed.

Moreover, it is also conceivable to calculate the charging current FastCC_I by using the surface temperature of the battery BT in place of the estimated internal temperature; however, since there is a time lag until heat generated in the inside of the battery BT transmits to the surface of the battery BT, responsiveness of the charging current FastCC_I is degraded. Moreover, when heat is suddenly generated in the inside of the battery BT, sensing thereof will be delayed since there is a time lag. In the charging system 1 according to the second embodiment, the estimated internal temperature of the battery BT is used, and accordingly, such responsiveness to the heat generation can be improved.

Characteristics During Charging

Next, effects of the charging system 1 according to the second embodiment will be described in detail by using comparative examples.

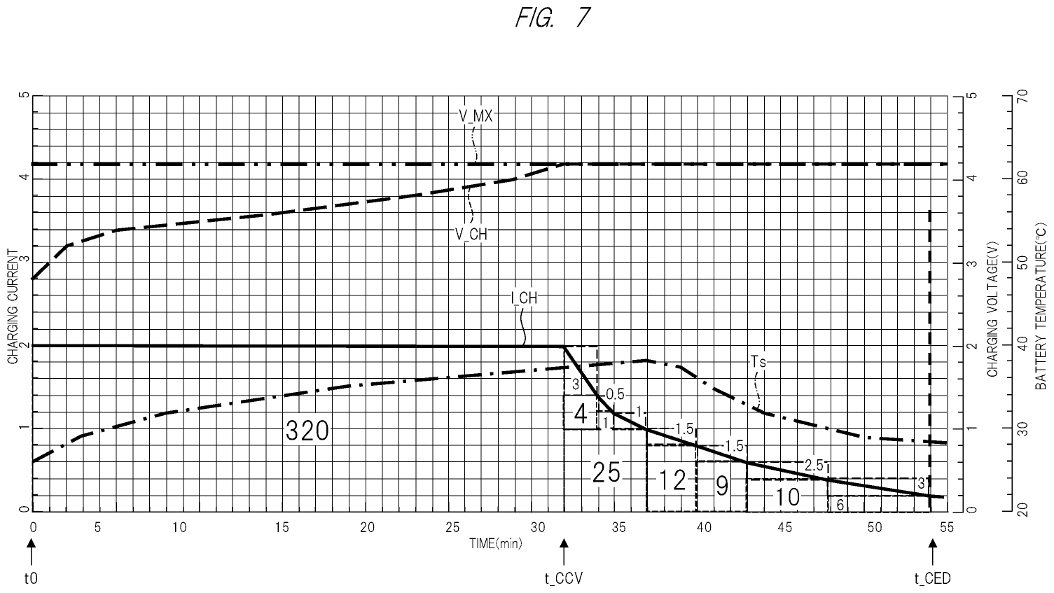

FIGS. 7 to 10 are characteristic diagrams showing characteristics during charging in Comparative examples 1 to 4, and FIG. 11 is a characteristic diagram showing characteristics of the charging system according to the second embodiment. FIGS. 7 to 11 are drawn on the basis of results of simulations implemented by the inventors.

In each of FIGS. 7 to 11, a horizontal axis represents a time, a vertical axis on the left side in the drawing represents the charging current of the battery BT, and a vertical axis on the right side in the drawing represents the charging voltage and temperature of the battery BT.

Moreover, in each of the drawings, each square surrounded by ruled lines represents a charge capacity, and 400 squares are equivalent to a full charge capacity in which the battery is charged by 100%. Numbers written on the squares indicate charge capacities charged until that time. For example, in FIG. 7, a number “320” represents that a charge capacity charged from a time t0 until a time t_CCV is equivalent to 320 squares. A charge capacity charged from the time t_CCV until a time t_CED is represented by the sum of numbers written on the squares.

### Comparative Example 1

FIG. 7 shows characteristics of a charging system according to Comparative example 1. In this Comparative example 1, the charging of the battery is started at the time t0, and the charging of the battery is ended at the time t_CED. The charging of the battery is performed in order of constant current charging (CC) and constant voltage charging (CV). That is, at around the time t_CCV, the charging switches from the constant current charging to the constant voltage charging.

In FIG. 7, a broken line V_CH indicates the voltage of the battery, and a solid line I_CH indicates the charging current supplied to the battery. Moreover, a single dashed line Ts indicates the surface temperature of the battery. In Comparative example 1, a maximum current value of the charging current I_CH is limited to 2 amperes (A), and an ambient temperature is set to 25° C. Moreover, a chain double-dashed line V_MX indicates a maximum charging voltage value of the battery.

As shown in FIG. 7, in Comparative example 1, while the surface temperature of the battery is kept low, a time period until the time t_CED when the charging of the battery is completed is as long as approximately 54 minutes, so that the charging time required for the charging is long.

### Comparative Example 2

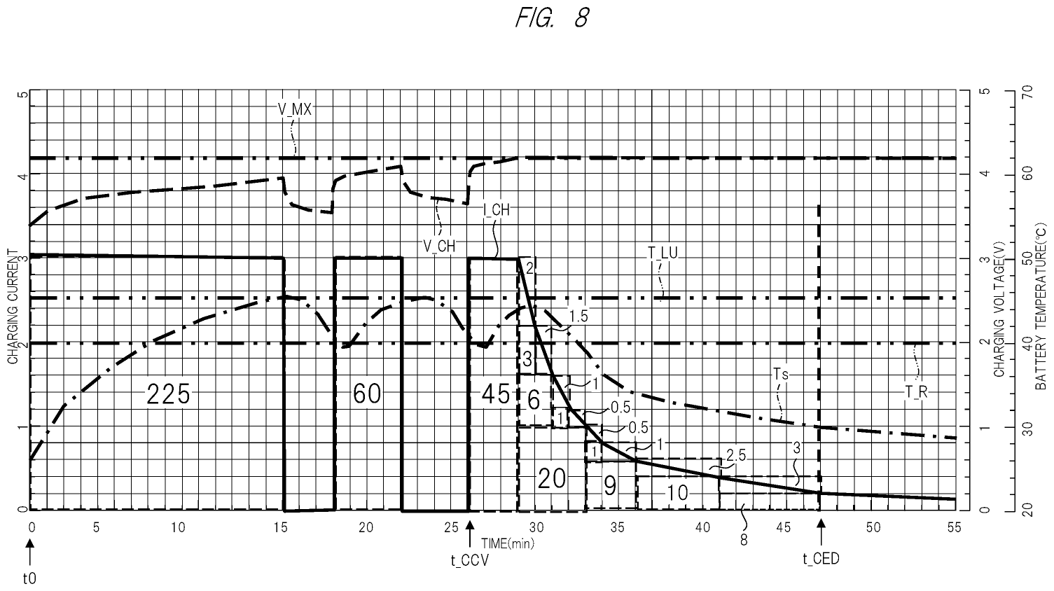

FIG. 8 shows characteristics of a charging system according to Comparative example 2. Comparative example 2 is similar to Comparative example 1. A difference of Comparative example 2 from Comparative example 1 is that the maximum current value of the charging current I_CH is limited to 3 amperes (A). Moreover, in FIG. 8, a chain double-dashed line T_LU indicates an upper limit (a charging temperature upper limit) of the charging temperature, and a chain double-dashed line T_R indicates a charging restart temperature of restarting the charging. In Comparative example 2, a control is performed so that the charging is stopped when the surface temperature of the battery reaches the charging temperature upper limit T_LU, and so that the charging is restarted when the surface temperature of the battery falls to the charging restart temperature or less.

In Comparative example 2, since the current value of the charging current I_CH is high (3 amperes), it is possible to increase the charge capacity in a short time. However, the charging current I_CH is high, and accordingly, as shown in FIG. 8, the surface temperature Ts of the battery rises to reach the charging temperature upper limit T_LU, where the charging is stopped (the charging current I_CH decreases). Thereafter, the surface temperature Ts decreases to the charging restart temperature T_R or less, whereby the charging is restarted. Hence, in Comparative example 2, such a time period while the fast constant current charging is not performed occurs frequently.

### Comparative Example 3

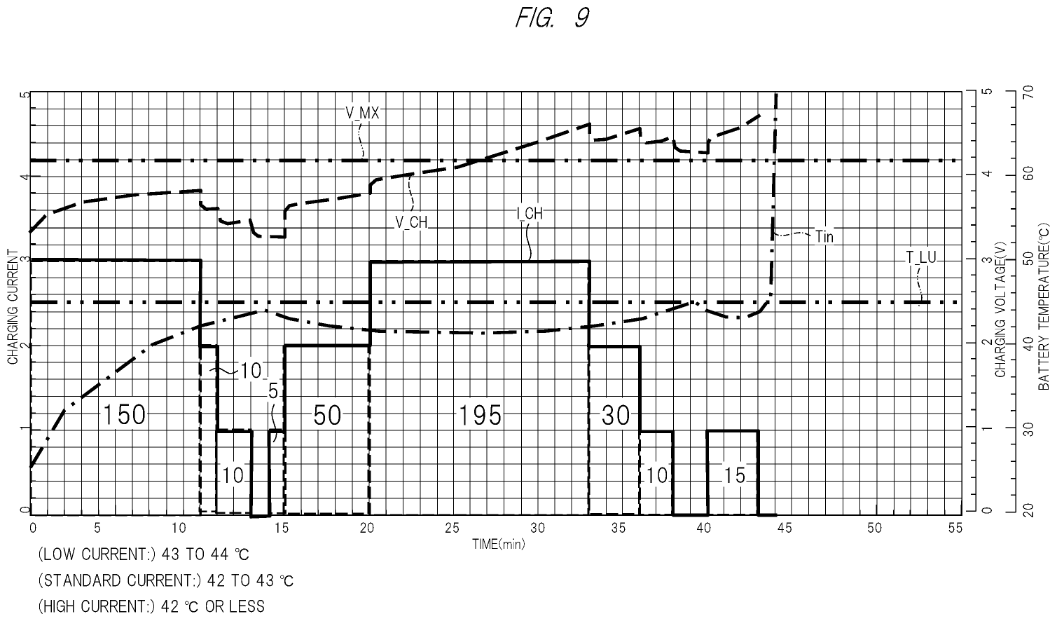

FIG. 9 shows characteristics of a charging system according to Comparative example 3. The charging system according to Comparative example 3 is configured to estimate the internal temperature Tin of the battery from the ambient temperature of the battery, and to perform a control (a temperature control) for the charge on the basis of the estimated internal temperature Tin. That is, the charging system does not perform the fast constant current charging or the fast constant voltage charging, but controls the value of the charging current I_CH on the basis of the estimated internal temperature. In the example shown in FIG. 9, the charging current I_CH is set to a high current value (3 amperes) when the internal temperature Tin (the estimated internal temperature) of the battery is low (42° C. or less), the charging current I_CH is set to a standard current value (2 amperes) when the internal temperature Tin is a standard temperature (42° C. to 43° C.), and the charging current I_CH is set to a low current value (1 ampere) when the internal temperature Tin is a high temperature (43° C. to 44° C.).

As shown in FIG. 9, when the internal temperature Tin of the battery is the charging temperature upper limit T_LU or less, the value of the charging current I_CH changes according to the temperature. The charging by the charging current I_CH progresses, whereby the voltage V_CH of the battery rises, and as shown in FIG. 9, the voltage ✓ CH exceeds the maximum charging voltage value V_MX. When the voltage V_CH of the battery exceeds the maximum charging voltage value V_MX, the battery is overcharged, and it is apprehended that gas ejection, firing and the like may occur when the battery is overcharged beyond such a limit.

### Comparative Example 4

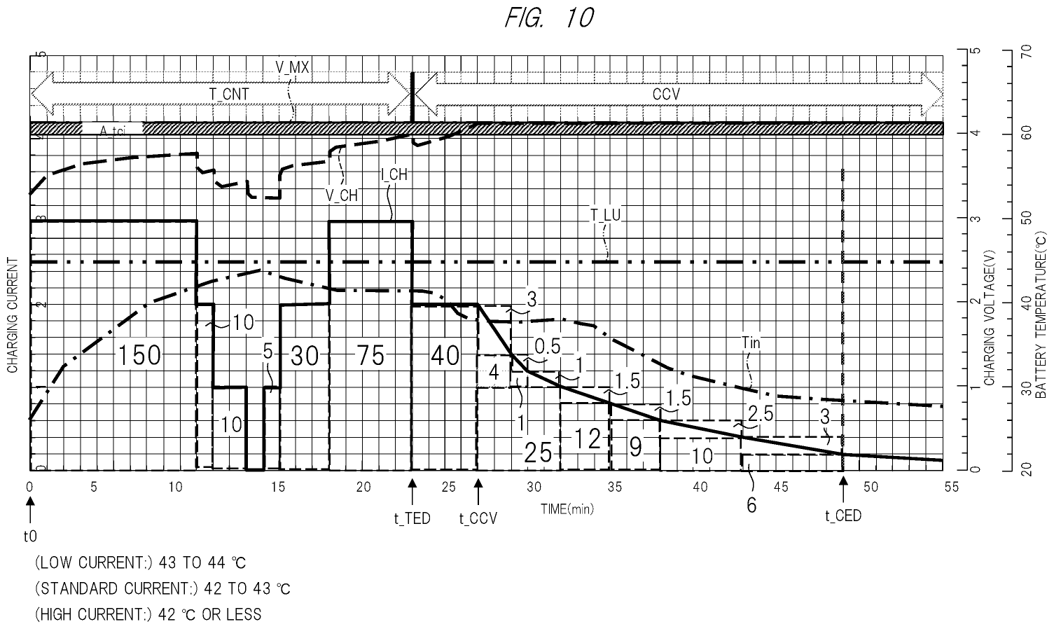

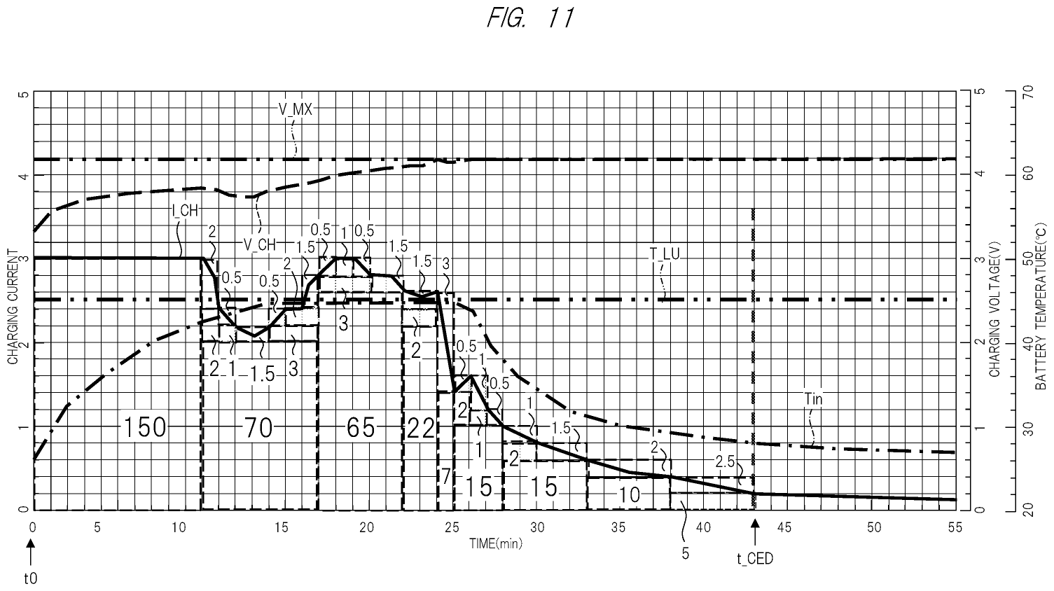

FIG. 10 shows characteristics of a charging system according to Comparative example 4. Comparative example 4 is one in which Comparative example 2 and Comparative example 3 are combined with each other. That is, at the time when the charging is started, the temperature control T_CNT that is mentioned in Comparative example 3 and controls the charging current I_CH on the basis of the internal temperature Tin is performed, and when the voltage V_CH of the battery reaches a battery internal temperature control inhibition region A_Tci (a time t TED), the control switches to the fast constant current charging and the fast constant voltage charging (a fast charging control CCV), which are mentioned in Comparative example 2. In the fast charging control CCV, the maximum current of the charging current I_CH is set to 2 amperes unlike Comparative example 2.

In the temperature control T_CNT, the battery is charged while the value of the charging current I_CH is being changed according to the internal temperature Tin. In Comparative example 4, even if the internal temperature Tin does not exceed the charging temperature upper limit T_LU, when the voltage V_CH of the battery reaches the battery internal temperature control inhibition region A_Tci, the control shifts to the fast charging control CCV in which the maximum current is set to 2 amperes. Since the maximum current is 2 amperes, the voltage V_CH of the battery drops when the control shifts to the fast charging control CCV. Thereafter, the charging switches from the fast constant current charging to the fast constant voltage charging at the time t_CCV, and accordingly, the voltage V_CH of the battery can be prevented from exceeding the maximum charging voltage V_MX.

In Comparative example 4, in order to set the battery internal temperature control inhibition region A_Tci in the charging temperature control T_CNT, the charging current I_CH is controlled so that the temperature range is narrower than an internal temperature range that should be naturally permitted. That is, it is made necessary to ensure a margin in order to switch the control from the charging temperature control T_CNT to the fast charging control CCV, and the charging time until the end of the charging is extended.

### Characteristic Example of Second Embodiment

In accordance with the charging system 1 according to the second embodiment, the value of the charging current I_CH changes to a small extent according to the internal temperature Tin of the battery BT as shown in FIG. 11. That is, such a time period as mentioned in Comparative example 2, while the fast constant current charging is not performed, can be eliminated. Moreover, since this internal temperature Tin is calculated on the basis of the surface temperature Tp of the battery BT, such an internal temperature Tin that satisfactorily follows a temperature change of the battery BT can be estimated. Further, the charging current I_CH can be caused to follow the change of the internal temperature Tin more satisfactorily.

Moreover, in the second embodiment, in both of the fast constant current charging and the fast constant voltage charging, the charging current FastCC_I is calculated in accordance with the estimated internal temperature Tin, and the charging current FastCV_I is calculated at the time of the fast constant voltage charging. A current that is based on the charging current with a smaller current value between the calculated charging currents FastCC_I and FastCV_I is used as the charging current I_CH that charges the battery BT, and accordingly, such overcharging as mentioned in Comparative example 3 can be prevented from occurring. Moreover, even if such a margin as mentioned in Comparative example 4 is not provided, the charging can be switched from the fast constant current charging to the fast constant voltage charging. As a result, in the charging system 1 according to the second embodiment, the charging time can be shortened to approximately 43 minutes as shown in FIG. 11. In the charging system 1 according to the second embodiment, naturally, the charging time is shortened also in comparison with Comparative example 1.

### Third Embodiment

In a third embodiment, a description will be given of a charging control method effective when the battery BT is composed of the plurality of battery cells BTC1 to BTCn as shown in FIG. 4.

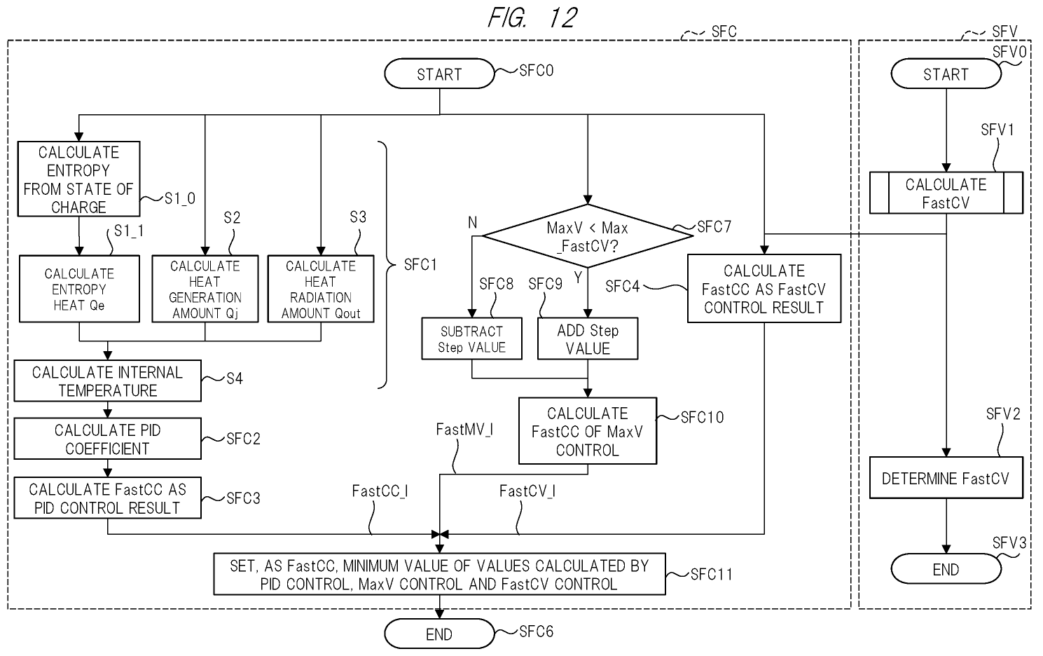

FIG. 12 is a flowchart showing operations of a charging system according to the third embodiment. Since FIG. 12 is similar to FIG. 6, differences of FIG. 12 from FIG. 6 will be mainly described. Main differences between FIG. 12 and FIG. 6 are that, in FIG. 12, Steps SFC7 to SFC10 are added to Step SFC related to the fast constant current charging, and Step SFC5 (FIG. 6) is changed to Step SFC11.

The battery cells BTC1 to BTCn which constitute the battery BT sometimes have different characteristics from one another. When the characteristics are thus different from one another, the battery cells differ from one another in terms of the charged state (for example, the voltage of each battery cell), for example, when being charged, resulting in an occurrence of a malfunction. Steps SFC7 to SFC10 are steps executed in order to equalize the states of charge between the battery cells.

In Step SFC7, a maximum voltage Max FastCV when the battery cell (for example, BTC1 in FIG. 4) is subjected to the fast constant voltage charging and a voltage MaxV of the battery cell BTC1 at the current time are compared with each other. When the voltage MaxV at the current time is smaller than the maximum voltage Max FastCV (Y), then Step SFC9 is executed. In contrast, when the voltage MaxV at the current time is equal to or larger than the maximum voltage Max FastCV (N), then Step SFC8 is executed.

In Step SFC8, a predetermined current value (a step value) is subtracted from the value of the charging current at the current time. Meanwhile, in Step SFC9, a predetermined current value (a step value) is added to the value of the charging current at the current time. On the basis of a value of the charging current, which is obtained in Step SFC8 or SFC9, a value of a charging current FastMV_I of a control (a MaxV control) based on the voltage MaxV of the battery cell is calculated in Step SFC10.

In Step SFC11, the charging current FastCC_I calculated in Step SFC3, the charging current FastCV_I calculated in Step SFC4, and the charging current FastMV_I calculated in Step SFC10 are compared with one another, and the charging current with a smallest value is selected. The charging current thus selected is set as a charging current that charges the battery BT.

In the third embodiment, when the battery is composed of the plurality of battery cells, a phenomenon that the voltages of the battery cells differ from one another due to the charging can be reduced.

Moreover, in Step SFC11, the charging current with a smallest current value is set as such a current that charges the battery BT. Hence, when the charging current FastMV_I is smaller than the charging currents FastCC_I and FastCV_I, the battery BT will be charged with the charging current FastMV_I. As a result, in accordance with the third embodiment, it becomes possible to reduce an influence from characteristic variations between the battery cells while preventing the overcharging of the battery and also the occurrence of the charging time loss as mentioned in the second embodiment.

Supplementary Note

In the present specification, inventions are also described besides the inventions described in the scope of claims. Representative inventions will be listed below.

(A) A charging system comprising:

a battery pack including a battery and a semiconductor device coupled to the battery; and

a charging device coupled to the battery pack and configured to charge the battery based on battery state information related to the battery, the battery state information being supplied from the semiconductor device,

wherein the semiconductor device comprises:

a control unit configured to be supplied with a charging current of the battery, a voltage of the battery, and a surface temperature of the battery, and estimates an internal temperature of the battery; and

a memory configured to store the internal temperature estimated by the control unit, and

wherein the control unit:

calculates entropy heat of the battery at a predetermined time by using the supplied charging current and an internal temperature at a time before the predetermined time, the internal temperature being stored in the memory;

calculates a heat generation amount of the battery from the supplied charging current;

obtains a temperature difference between the internal temperature at the time before the predetermined time, the internal temperature being stored in the memory, and the supplied surface temperature, and calculates a heat radiation amount of the battery from the temperature difference; and

estimates an internal temperature of the battery at the predetermined time by using the calculated entropy heat, the calculated heat generation amount, and the calculated heat radiation amount.

(A-1) The charging system according to (A),

wherein the semiconductor device determines, based on the estimated internal temperature, the charging current that charges the battery, and supplies the determined charging current as the battery state information to the charging device.

(A-2) The charging system according to (A-1),

wherein the battery pack further comprises:

a temperature sensor provided on a surface of the battery; and

a shunt resistor coupled between the battery and the charging device, and

wherein a temperature measured by the temperature sensor is supplied as the surface temperature of the battery, and a current flowing through the shunt resistor is supplied as a current of the battery to the semiconductor device.

(A-3) The charging system according to (A-1),

wherein the semiconductor device calculates a constant voltage charging current when the battery is charged with a constant voltage, compares the calculated constant voltage charging current and a charging current determined based on the estimated internal temperature with each other, and supplies the charging current with a smaller value as the battery state information to the charging device.

While the invention made by the inventor thereof has been specifically described on the basis of the embodiments thereof, needless to say, the present invention is not limited to the above-described embodiments, and is modifiable in various ways within the scope without departing from the spirit thereof. For example, in the present specification, the example of adopting the fast charging (the fast constant voltage charging and the fast constant current charging) has been described; however, the term “fast” does not mean that the charging current and the charging voltage are limited to specific ranges.

What is claimed is:

1. A semiconductor device for controlling charging a battery, comprising:
a control unit configured to be supplied with a charging current of the battery, a voltage of the battery, and a surface temperature of the battery, and estimate an internal temperature of the battery; and
a memory configured to store the internal temperature estimated by the control unit,
wherein the control unit is configured to:
calculate entropy heat of the battery at a predetermined time by using the supplied charging current and an internal temperature at a time before the predetermined time, the internal temperature being stored in the memory;
calculate a heat generation amount of the battery from the supplied charging current;
obtain a temperature difference between the internal temperature at the time before the predetermined time, the internal temperature being stored in the memory, and the supplied surface temperature, and calculates a heat radiation amount of the battery from the temperature difference; and
estimate an internal temperature of the battery at the predetermined time by using the calculated entropy heat, the calculated heat generation amount, and the calculated heat radiation amount.

2. The semiconductor device according to claim 1,
wherein the memory is configured to store plural pieces of entropy, each of which corresponds to a charged state of the battery, and
wherein the control unit is configured to:
select entropy from the plural pieces of entropy stored in the memory, the entropy corresponding to a charged state of the battery at the predetermined time; and
calculate the entropy heat of the battery by using the selected entropy.

3. The semiconductor device according to claim 2,
wherein the memory is configured to store an internal resistance of the battery, and
wherein the control unit is configured to calculate the heat generation amount of the battery by using the internal resistance.

4. The semiconductor device according to claim 2,
wherein the memory is configured to store an open voltage of the battery, and
wherein the control unit is configured to calculate the heat generation amount of the battery by using the open voltage.

5. The semiconductor device according to claim 3,
wherein the memory is configured to store a temperature resistance of the battery, and
wherein the control unit is configured to calculate the heat radiation amount of the battery by using the temperature resistance.

6. The semiconductor device according to claim 1,
wherein the charging current that charges the battery is determined based on the internal temperature of the battery, the internal temperature being estimated by the control unit.

7. The semiconductor device according to claim 6,
wherein the charging current that charges the battery is determined based on a temperature difference between a set target temperature and the internal temperature of the battery, the internal temperature being estimated by the control unit.

8. The semiconductor device according to claim 7,
wherein the charging current that charges the battery is determined by a PID control using, as inputs, the target temperature and the estimated internal temperature of the battery.

9. The semiconductor device according to claim 6,
wherein, at a time of charging the battery at a constant voltage, the control unit is configured to calculate a constant voltage charging current flowing through the battery, and
wherein the control unit is configured to:
compare the charging current determined by using the estimated internal temperature of the battery and the calculated constant voltage charging current with each other; and
select the charging current with a smaller value as the charging current that charges the battery.

10. The semiconductor device according to claim 9,
wherein the battery comprises a plurality of battery cells,
wherein, based on a maximum voltage of the battery cells, the control unit is configured to calculate the charging current at the time of charging the battery, and
wherein the control unit is configured to:
compare the charging current determined by using the estimated internal temperature of the battery, the constant voltage charging current, and the charging current calculated based on the maximum voltage of the battery cells with one another; and
select the charging current with a smallest value as the charging current that charges the battery.

11. A control method of charging a battery, the control method comprising:
storing an internal temperature of the battery in a memory at a time before a predetermined time;
calculating entropy heat of the battery at the predetermined time by using a current of the battery at the predetermined time and an internal temperature of the battery, the internal temperature being stored in the memory;
calculating a heat generation amount of the battery by using the current of the battery at the predetermined time;
obtaining a temperature difference between the internal temperature of the battery, the internal temperature being stored in the memory, and a surface temperature of the battery at the predetermined time, and calculating a heat radiation amount from the obtained temperature difference; and
estimating an internal temperature of the battery by using the calculated entropy heat, the calculated heat generation amount, and the calculated heat radiation amount.

12. The control method of charging a battery according to claim 11,
wherein a charging current that charges the battery is determined based on the estimated internal temperature of the battery.
